(19) United States
(12) Patent Application Publication
(10) Pub. No.: US 2002/0199153 A1
(43) Pub. Date: Dec. 26, 2002

(54) Sampling method for use with bursty communication channels

(76) Inventor: Thomas G. Fall, Los Gatos, CA (US)

Correspondence Address: Keith D. Nelson, Lockheed Martin Corporation, Building 220, Mail Stop A08, P.O. Box 49041, San Jose, CA, 95161-9041, US

(21) Appl. No.: 09/887,888

(22) Filed: Jun. 22, 2001

(51) Int. Cl. H03M 13/00

(52) U.S. Cl. 714/781

(57) ABSTRACT

An error correction method wherein an incoming data stream is divided into symbols. The divided data stream is sampled in threads, with samples taken at fixed time intervals. The fixed time intervals are slightly longer than the time interval of the bursts of data. A correction symbol is thus mixed with symbols of the divided data stream that have a fixed time separation. This generates an error corrected data stream. In a second embodiment, the same correction symbol is inserted in more than one thread. The threads are selected so that they partially overlap. Thus, a noise burst on the channel that overwhelms one of the threads will be within the limits of another one of the threads. The symbols that overlap may be determined using the overlapping symbols of the threads that are not overwhelmed, thus allowing the remainder of the non-overlapped threads to be determined.

### BACKGROUND

The present invention relates generally to error correction for communication links, and more particularly, to an error correction method for use with bursty (noisy) communication channels such as satellite communication links and scratched compact disks, and the like.

The goal of any error correcting scheme is to compensate for random errors in the transmission medium (including the recorded media). In particular, many transmission media are susceptible to burst errors, where the errors tend to occur in groups. For instance, compact disks produce error bursts caused by dust or scratches. RF transmissions have error bursts caused by lightning. The general approach is to use an error correction process and to spread out the burst so that the error correction process does not get overwhelmed. The present approach differs in how the spreading of the burst is accomplished.

Bit level or byte level interleaving is the current method of spreading the effects of a noise burst out over a longer interval. Interleaving mixes a given symbol with symbols that are in other fixed positions in the data stream regardless of data rate. The span of error correction used in the conventional interleaving approach can be no longer than the length of a block of data.

Referring to FIGS. 1-3 of the drawings, the typical conventional block interleaving approach is as follows. As is shown in FIG. 1, data is read into a block m wide by n deep (the data may be either read in by columns or by rows). As is shown in FIG. 2, a number (r) of error correction symbols are added to each row. Symbols are read out vertically. Thus, in the block interleaving approach, the full matrix must get filled, and the error correction symbols are all located at the end of the block's transmission. Referring to FIG. 3, if a noise burst happens, the following occurs. For a selected row, only two symbols are affected by the noise burst, so if there are more than 4 error correcting symbols for that row, the errors would get corrected.

Numerous patents were uncovered in a computer search investigating the present invention, and which are generally outlined below. U.S. Pat. No. 4,700,363 discloses a data communication method and apparatus wherein a “data stream is impressed on a carrier by forming from the data stream a succession of binary symbol words which control the modulation level of the carrier during respective modulation time intervals. To generate the symbol words from the data stream, the latter is first divided into a base bit stream and one or more second bit streams. These second streams are then subjected to error control coding before being used to define the least significant bits of the symbol words; the most significant bits are provided by the base bit stream. As a result, although the least significant bits of the transmitted symbol words are more prone to noise corruption than the most significant bits this tendency is compensated for by the error coding employed. The overall effect is to minimize power requirements while retaining good bandwidth efficiency.”

U.S. Pat. No. 5,325,371 discloses “an error correction encoding apparatus for processing input data with an encoding for error correction. The apparatus includes first delay circuitry for applying differing delay to data words to convert input data in a first array state into data words in a second array state, a first error correction encoder for generating first check words from data words in the second array state, second delay circuitry for applying differing delay to the data words in the second array state and the first check words to generate data words and check words in a third array state, and a second error correction encoder for generating second check words from the data words and the check words in the third array state, with the delays applied by the first and second delay circuitry set so that the array states of the data words in the first and the third array states are the same. The error correction decoding apparatus includes a first error correction decoder for processing input data words and check words in a third array state by error correction by a second error correction code using a second check word series, first delay circuitry for applying differing delay to the corrected data words and check words from the first error correction decoder to generate data words in a second array state and first check words, a second error correcting decoder for error-correcting the data words in the second array state by a first error correction code using the first check words, and second delay circuitry for applying differing delay to the corrected data words from the second error correcting decoder to generate data words in a first array state.”

U.S. Pat. No. 5,392,299 discloses a triple orthogonally interleaved error correction system wherein “detection and correction of errors in digital data transmitted by or stored in a media channel is provided by processing the data through a triple orthogonally interleaved error correction system. On the transmit/store side of the system, the data is encoded three times prior to placement in the media channel with two different interleaving steps performed between the encoding steps. The first interleave is an orthogonal row shuffling interleave that provides enhanced protection against burst errors. On the receive/play back side, the data is decoded and deinterleaved, with included errors detected and corrected to enable recovery of the original data. To enhance the error correction, a circuit is used for generating a symbol accurate error flag identifying symbols containing errors thereby allowing the error correcting decoders to focus on and correct the data.”

U.S. Pat. No. 5,491,701 discloses a “burst error correction system comprising a CRC generator/checker; a syndrome/ECC generator; and an error corrector. Using code-word data, the CRC generator/checker generates m number of CRC bytes. The CRC bytes are shifted out to the syndrome/ECC generator for use in the generation of a plurality of ECC bytes. In a write operation, syndrome/ECC generator groups the data bytes and the CRC bytes for each code-word into a predetermined number of interleaves. The ECC bytes are generated so that the sum of the bytes in each interleave for a code-word is zero, and so that the ECC bytes generated by the syndrome/ECC generator constitute at least L number of consecutive roots of the code-word. The syndrome/ECC generator comprises an interleave dependent ECC factor subgenerator and two interleave independent ECC factor subgenerators. In the general processing of a read code-word, in a first state of operation the entire code-word is inputted, for regenerating CRC bytes (and adding the regenerated bytes to the received CRC bytes of the code-word, thereby yielding CRC check remainder bytes) and for generating syndromes. The syndromes are utilized to determine if the code-word is correct or if an error burst has occurred. When a portion of an error burst occurs in the data portion, a data error burst processing and correction state is begun. When a portion of the error burst occurs in the CRC portion, a CRC error burst processing state is begun.”

U.S. Pat. No. 5,428,627 discloses a “method and apparatus for converting input symbols of a fixed length, to output symbols of a greater fixed length. Input symbols are received one at a time and are clocked into the staging register. When a new input symbol is loaded into the staging register, the contents of the first stage are moved to a second stage of the staging register. The new input symbol is loaded into the cells of the first stage. Multiplexers select the contents of cells of the staging register to form the output symbol. A modulo-x counter counts the incoming input symbols. The output of the counter determines which cells the multiplexer selects. Initially, the first stage of the staging register is preloaded with a predetermined pad symbol, and the modulo-x counter is preset. The first output symbol consists of a number of bits from the pad symbol and those bits of the first input symbol needed to complete the first output symbol.”

U.S. Pat. No. 4,856,003 discloses an encoder that “encodes a sector of data to produce ECC symbols using a GF(210) code by first appending one or more pseudo data bytes to the sector data bytes. The data string of sector data bytes and pseudo data bytes are then encoded to produce a desired number of 10-bit ECC symbols. Two selected bits from each ECC symbol are compared to a known bit pattern. If the selected bits match the pattern, the bits are truncated and the remaining 8-bit symbols are concatenated with the data string to form a code-word. The code-word bytes can later be decoded, and any error correction performed, by appending the bit pattern as necessary. If the selected bits do not match the pattern, the pseudo data bytes are modified such that encoding the data bytes and the modified pseudo data bytes produce 10-bit ECC symbols with the selected bits matching the bit pattern. The selected bits are then truncated and the remaining 8-bit symbols are concatenated with the data string to form the code-word.”

U.S. Pat. No. 4,599,722 discloses apparatus that permits “the correction of a single bit error occurring in a sequence of data packets (e.g. bytes) comprising data bits. An encoder produces an error correction packet (e.g. byte), the value of which is determined algebraically from the value of bits in the data sequence. All data packets and the error correction packet have a predetermined panty. A decoder receives the sequence of data packets and error correction packet. If a single bit error in the data bits has occurred during transmission, one data packet is identified as having in it the bit in error. Algebraically, the data bit in error is identified and corrected.”

U.S. Pat. No. 5,200,962 discloses a “combined data compression/error correction system suitable for use in synchronous communication utilizes a data compressor to produce variable rate compressed data from synchronous data. The variable rate compressed data is applied to a FIFO memory which is monitored to determine when the amount of data in the FIFO drops below a predetermined threshold. When it drops below this threshold, an error correction code generator generates a separator character and an error correction code which is appended to the compressed data in the FIFO. Thus, the additional bandwidth created by data compression is used to provide enhancement to the data integrity by providing a variable level of error correction varying in accordance with the free bandwidth generated by the data compressor.”

U.S. Pat. No. 5,051,998 discloses a “deinterleaving and error correction system which is utilized in a playback system of an optical recording disk apparatus. As each block of sector data, encoded for example with the Reed-Solomon error correction code with block interleaving, is read from the disk, the positions within the data block at which drop-out of the playback signal occurs are respectively stored in a memory in which the data symbols are also stored, with these drop-out positions being stored as error position data. Error correction processing is executed using the error position data in conjunction with the code words, enabling the maximum number of correctable errors for each sector to be substantially increased using a simple system configuration.”

U.S. Pat. No. 5,467,359 discloses “apparatus for generating and checking the error correction codes of messages in a message switching system” and includes an “error control circuit which computes for each burst of a message (for a destination unit) an error correction code as a function of an initial error correction code at the first burst of the message or of the error correction code of the previous burst and of the data bytes of the burst. The burst error correction code is sent on a medium which is separate from the data transport medium as a companion of the burst. Also, the error control circuit receives the burst error correction code from an origin unit and generates the burst error correction code to be compared with the received burst error correction code. If a mismatch is detected, the burst found in error is flagged.”

U.S. Pat. No. 5,357,527 discloses a “method for transmitting and verifying the accuracy of a software program, expressed as a stream of J bits. A first forward error correction error coding, detection and correction (ECDC) procedure is applied to the program, where the first ECDC procedure is expressible as a stream of K1 error coding bits plus L1 additional bits representing the procedure for determining the values of the K1 bits and for detecting the presence of and correcting an error in the original stream of J bits plus the K1 error coding bits, as received by a recipient. A second ECDC procedure is then applied to the K1+L1++bits++ used in the first ECDC program, where the second ECDC procedure is expressible as a stream of K2 error coding bits plus L2 additional bits representing the procedure for determining the values of the K2 bits and for detecting the presence of and correcting an error in the (K1+L1 bits that represent the first ECDC procedure. The second ECDC procedure is applied to check the accuracy of transmission of the bits representing the first ECDC procedure, which is applied to the software program itself. The bit stream of J bits can be decomposed into 8 or 16 mutually exclusive subsidiary bit streams, to each of which the above error checking procedure is applied, to take advantage of certain kinds of error statistics that may be present.”

U.S. Pat. No. 4,541,091 discloses a “method and apparatus for detecting and correcting code errors in processing a digital signal such as a digital audio signal are disclosed. An error word correcting parity word generated from a plurality of data words is added to the plurality of data words to form a first frame, and the data words and the parity word of a plurality of different first frames are distributed in a second frame and a plurality of additional parity words for detecting and correcting error words in the second frame are added to the second frame to form a Reed-Solomon code. The code errors are detected and corrected using this code. A code error rate counter is provided, and when an output of the code error counter exceeds a predetermined count, the code error correction is inhibited for a predetermined time period or until the code error rate reaches a second predetermined code error rate.”

U.S. Pat. No. 4,649,542 discloses a “method of transmitting a digital signal in the form of successive signal frames containing codes for detecting and correcting errors of the digital signal for reducing degradation in the quality of the reproduced sound due to generation of the code errors in a digitized audio signal transmission system. An analog signal such as an audio signal is sampled and subjected to A/D conversion. The sample word thus obtained is divided into a plurality of symbol elements. Parity words for detecting and correcting code errors are added to every group of a predetermined number of the information symbols through an interleave procedure before being transmitted. The method includes the steps of applying a first frame of symbols, taken one from each input channel, and having a first arrangement state, to a first error correcting code encoder to generate a series of first parity words; delaying each of the symbols in the first frame and each of the first parity words by a respective different delay time in a unit of the sample word at a delay line to provide a resulting second frame of symbols in a second arrangement state; applying the second frame of symbols to a second error correcting code encoder to generate a series of second parity words; and transmitting said second frame of symbols together with said second parity words.”

U.S. Pat. No. 4,901,319 discloses a “transmitter has an adaptive interleaver that sets an interleaving interval in accordance with the fading characteristic of a channel and transmits in another channel. The interleaver duration is indicated by a synchronization signal and typically is 3 to 10 times the mean time between fades (decorrelation time). If the two channels substantially differ in frequency, a scaling factor can be used. A receiver has an adaptive deinterleaver that has a deinterleaving time in accordance with the synchronization signal occurring at the interleaving interval.”

U.S. Pat. No. 4,750,178 discloses in an “error correcting method for a block of data having first and second error correction codes based on first and second series of symbols within the data block, error correction is performed repeatedly by alternately using the first and second code series, to achieve the maximum error correcting capability, without reference to the result of a previous error correction using the other series.”

U.S. Pat. No. 5,365,525 discloses a “method for reducing bandwidth of a wireline communication path”, wherein, “within a fixed infrastructure of a communication system, message portions of code words that are found to be uncorrectable (erasures) are transmitted with a predetermined number of bits in place of the parity portion associated with those code words. These predetermined number of bits indicate the existence of the erasures, which can be reproduced for continued transmission to the final destination. By having the number of predetermined bits being less than the number of parity bits, the bandwidth requirement for wireline communication paths is reduced”

U.S. Pat. No. 5,136,592 discloses an “error detection and correction system for long burst errors” which “encodes data twice, once for error detection by using a cyclic redundancy check (CRC) code with a generator polynomial, g(x) in octal form: g(x)=2413607036565172433223 and a second time for error correction by using a Reed-Solomon error correction code. The system then uses the CRC code to check the data for errors. If errors are found the system uses the error location information supplied by the CRC code and the Reed-Solomon code to correct the errors.”

U.S. Pat. No. 5,408,477 discloses the use of “Q- or P-sequence error correction suitable for correcting errors of data stored in a CD ROM. Errors of data are corrected using a 2-word parity code added to the data and input pointers that have been set for the words that are presumed to be subjected to errors. Output pointers are set for respective words of data which are presumed not to be error-corrected completely.”

U.S. Pat. No. 4,802,173 discloses a “method of and device for decoding a block of code symbols which is distributed between code words in two ways, each code word being protected by a maximum distance separable code. A block of code symbols is protected by a product code or a pseudo product code. First of all, all syndrome symbols are formed and all code words having a syndrome which deviates from zero are provided with a flag. Each non-redundant symbol forms part of a first code word and also of a second code word, the numbers of flags of first and second code words being separately summed. The code words are successively addressed and an error location is determined. When an error location forms part of an incorrect first code word as well as of an incorrect second code word, it is corrected; if the second code word is not signaled as being incorrect, however, the error will not be corrected. After correction, the syndromes are updated, the flags being updated and the summing results being decremented only if the syndromes of both relevant code words are zero. In the opposite case the flags will remain unmodified for the time being.”

U.S. Pat. No. 4,559,625 discloses a “method and apparatus for interleaving block codes exploits helical symmetry whereby correspondingly positioned code symbols of code words of length n interleaved to depth i, i<n, are separated on the channel by i+symbol intervals where 1+i is averaged over the i correspondingly positioned symbols and ∥ are integers >1. The requirement for synchrony is reduced to a period counted modulo n instead of mod (nXi). For the case I=n−1, the total interleaving delay is reduced to 2(n−1)n and phase dependence of burst error onset is minimized. The performance of the deinterleaver is enhanced through a pseudo fade detector implemented by creating erasures prior to decoding, at certain positions for code-words subsequent to confirmed error. Synchronization of interleaver and deinterleaver is accomplished in apparatus which inspects all c contiguous bit patterns corresponding to a c-bit synch symbol. To each c contiguous bit pattern of the data stream there is associated a probability counter for incrementing when the synch pattern is detected and decremented otherwise. Maximum probability establishes synch.”

U.S. Pat. No. 4,633,486 discloses a “method and apparatus for synchronization by coherent reinforcement” wherein, for “each bit time of a data block, there is associated a counter which is incremented or decremented in accord with the congruence or non-congruence of the c bit sequence associated with the respective counter (for example, the first bit of the c bit sequence). The counters are initialized to an optimum non-zero value and after receiving a number of blocks of data, each containing one sync symbol, the synchronization is determined from the relative content of the counters.”

U.S. Pat. No. 5,550,849 discloses a “method and system for detecting and correcting all single bit errors in a data word, for detecting all 2-bit errors regardless of whether the two bits in error are consecutive, and for detecting all consecutive 3-bit and 4-bit errors regardless of whether the three bits or four bits are in a single byte. In a preferred embodiment, a set of check bits are established for the data word by exclusively ORing a set of data bits that are unique to each check bit, storing the data bits and check bits, retrieving the data bits, generating a new set of check bits from the retrieved data bits, and comparing the new set of check bits against the old set to establish a syndrome pattern which may be expressed as a hexadecimal for comparison with hexadecimals previously assigned to the data bits.”

U.S. Pat. No. 4,441,184 discloses that a “PCM digital signal is provided with double-interleaving and error-correction encoding to protect against errors occurring during transmission, which can be carried out by magnetic recording and reproducing. The PCM signal is processed as error correcting blocks of several data word sequences and an associated error correction word sequence, and the double-interleaved sequences are then transmitted as transmission blocks. Up to one erroneous word in each error correction block can be corrected by using the error correction word sequence. Any uncorrectable word can be compensated by substituting a synthetic word interpolated from immediately preceding and following data words known to be correct. The distance between successive data words is made as great as possible so that a long burst error is unlikely to affect the ability to compensate uncorrectable errors. To achieve this, alternate words of the PCM signal are distributed to odd and even groups of sequences, and the interleaving is carried out by imparting different delay times to the respective sequences such that the greatest delay time imparted to the odd sequences is less than the shortest delay time imparted to the even sequences. The error correction word sequence is provided with a delay time intermediate the greatest delay time of the odd sequences and the shortest delay time of the even sequences.”

U.S. Pat. No. 5,220,568 discloses that “channel encoded data (for example run length limited encoded data) is further encoded in accordance with a shift correction code prior to transmission. Upon reception, forward and backward shift errors present in the received channel encoded data are corrected by a shift correction decoder. The shift error correction is accomplished using a code, such as (for example) a BCH code over GF(p) or a negacyclic code, which treats each received symbol as a vector having p states. For a single shift error correction, p=3 and there are three states (forward shift, backward shift, no shift). In one embodiment, conventional error correction code-words which encode the user data may be interleaved within successive shift correction code-words prior to channel encoding, thereby enabling the error correction system to easily handle a high rate of randomly distributed shift errors (which otherwise would result in a high rate of short error bursts that exceed the capacity of the block error correction code).”

U.S. Pat. No. 5,010,554 discloses an “error correction method and apparatus” wherein, “for forward error correction, the least significant bit of each multibit symbol is encoded before transmission according to a block code that has an over-all parity bit. Since even syndromes can be produced by only an even number of errors and odd syndromes by an odd number of errors, a Chase decoder at the receiver considers either all double errors or all single errors and all triple errors that include the least reliable symbol in making the corrections to arrive at the most likely transmitted sequence.”

U.S. Pat. No. 5,511,078 discloses a “method and apparatus for correcting one B-bit block in error in a memory organized in words comprising N B-bit blocks consist of appending to the data bits to be written into the memory words a limited number of error correction bits computed from a depopulated parity check matrix which gives the capability of only correcting one block in error and improving the memory failure rate by cyclically reading each word, correcting a block found in error if any and writing the corrected data bits with the corresponding error correction bits in place of the read word.”

U.S. Pat. No. 5,390,195 discloses a “Miller-squared decoder with erasure flag output” that generates “a signal flag in response to illegal channel code patterns from an information channel. The signal flag may typically be used as an erasure flag by a subsequent error correction decoder. This erasure flag, being indicative of a data error position which can then be fed into a utilization circuit such as an error correction logic for performance improvement.”

U.S. Pat. No. 3,747,065 discloses an “error corrector” that “operates in conjunction with an error detector that provides outputs indicating that an error has occurred, the polarity of the error and an indication as to whether the error has occurred an even or odd time interval. The error corrector, upon being informed that an error has occurred, scans a group of previously estimated residual signals to determine which residual has the largest amplitude and a polarity opposite to the indicated error or polarity. The error corrector then identifies the particular digit estimate associated with the indicated largest residual and either adds or subtracts one level to that estimated digit, depending on the polarity of the indicated error. In most applications, the one correction corrects the detected error.”

U.S. Pat. No. 4,748,628 discloses a “method and apparatus for correcting errors in digital audio signals. In correcting errors in a received digital data signal having information data, a pair of parity series P and Q is determined by the information data and a CRC code is determined by the information data and the parity series. A parity check operation is performed for checking errors in either the parity series P or Q of the received digital data signal. An error correcting operation is performed for correcting erroneous data of either the P series or the Q series data on the basis of an error pointer generated by the CRC code included in the received digital data signal. A sequence of the parity check and error correcting operations is established for interposing at least one parity check operation among a series of error correcting operations.”

U.S. Pat. No. 4,291,406 discloses a “sequential decoder for error correction on burst and random noise channels using convolutionally encoded data. The decoder interacts with a deinterleaver which time demultiplexes data from a data channel from its time multiplexed form into a predetermined transformed order. The decoder includes a memory for storing a table of likelihood values which are derived from known error statistics about the data channel such as the probabilities of random errors and burst errors, burst error severity and burst duration. The decoder removes an encoded subblock of data from the deinterleaver and enters it into a replica of the convolutional encoder which calculates a syndrome bit from a combination of the presently received subblock together with a given number of previous subblocks. The syndrome bit indicates if the current assumption of the path through the convolutional tree is correct. Where there is no error in the channel, then the received sequence is a code word and the syndrome bit indicates that the correct path in the convolution tree is taken. For each received bit, and indicator bit is calculated which is a function of the difference between the current path and the received sequence. The sequential decoder employs the syndrome bit together with burst indicator bits to calculate a table address in a table of likelihood values and error pattern values. The likelihood value is used to update a total likelihood of error value and the error pattern value is used to change the received subblock of data.”

U.S. Pat. No. 5,483,541 discloses a “permuted interleaver/deinterleaver system for interleaving the bits of a digital communications system such that bursts of error bits are separated for more effective communications. The interleaver/deinterleaver system includes an interleaver and deinterleaver having a number of permuted rows of shift registers. The arrangement of the shift registers in the interleaver and deinterleaver can be determined by a permute number calculated in accordance with a specific communications implementation. As bits are input into the shift register of the inter-leaver, bits are output from the interleaver in order to establish a sequence of permuted data bits. A rotating switching mechanism systematically selects output bits from the shift register of the interleaver and applies the bits to a channel modulator/demodulator. The deinterleaver accepts the bits from the channel and restores the original bit order.”

U.S. Pat. No. 4,593,395 discloses an “error correction method for transferring word-wise arranged data, wherein two word correction codes are used successively, each code acting on a group of words while, therebetween, an interleaving step is performed. The actual transfer takes place by means of channel words for which purpose there are provided a modulator and a demodulator. Invalid channel words are provided with an invalidity bit in the demodulator. During the (possibly correcting) reproduction of the data words, the invalidity bits can be used in one of the two error corrections in various ways. When too many words of a group of code words are invalid, all words of the relevant group are invalidated. If a word comprising an invalidity bit is not corrected during correction by means of a syndrome variable, all words of the relevant group are invalidated. If the number of invalidity bits lies within given limits, they act as error locators so that the code is capable of correcting a larger number of words.”

U.S. Pat. No. 5,268,908 discloses “low data delay triple coverage code apparatus” that “allows on-the-fly error correction with fewer redundancy bytes than needed for a non-overlaid data redundancy structure thereby producing corrected data with a low data delay. The present apparatus divides a received block of data into a plurality of fixed size sub-blocks with the last sub-block size being smaller than or equal to the fixed sub-block size. Three predefined error correcting code generator polynomials are used to accumulate redundancy values for the sub-blocks. At the end of each sub-block one of the three pre-defined error correcting code generator polynomials will have accumulated a redundancy value across the present sub-block data and the previous two sub-blocks of data and redundancy. After the accumulated redundancy has been output as write data the predefined error correcting code generator polynomial is reset. Therefore, the redundancy information contained in each sub-block covers that subblock's data in addition to the data and redundancy in the previous two sub-blocks.”

U.S. Pat. No. 4,380,812 discloses a “data processing system in which the bits of each stored word in a memory thereof are refreshed periodically. At substantially the same time the refresh operation with respect to each word occurs, an error detection operation also occurs and, if an error is detected in a word that is being refreshed, the error is then corrected and the corrected word is written back into the memory. Thus, errors are continuously being checked with no more use of machine time then is required for the refresh operation. Error correction, when necessary, then takes place at a fixed frequency, a limit thereby being placed on the error correction process. If errors in a work are detected when the word is requested for access by a requester, the error is corrected before the word is supplied to the requester but the corrected word is not written back into memory at that time, the word in memory being again detected and corrected at its next refresh operation.”

U.S. Pat. No. 4,276,647 discloses a “circuit and method for the high speed generation and comparison of Hamming codes to enable the correction of an error burst. The circuit generates or compares n Hamming codes simultaneously with the data field transmission. Each code word is associated with a data field word comprising every nth bit. The resultant system corrects error bursts of up to n bits. Additional circuitry is included to enable the correction of error bits in parallel, increasing the system bandwidth.”

U.S. Pat. No. 5,371,751 discloses a “method of correcting triple-coded data, in which data coded in three different directions is subjected to error correction by referring to first, second and third codes, as well as a first flag determined by the first code and a second flag determined by the second code and other conditions, whereby this method demonstrates high error correcting performance with respect particularly to a burst error.”

U.S. Pat. No. 4,697,212 discloses a “method of recording a digital data signal, such as an audio PCM signal, onto a recording medium in the longitudinal direction thereof, together with an apparatus which is suitable for this recording method. Even-numbered words and odd-numbered words in a digital data signal are recorded on a first track group and a second track group, respectively, which are separated from each other in the widthwise direction of a recording medium, to prevent a series of words becoming error words because of, for example, a flaw in the recording medium in the longitudinal direction thereof. The data format is changed at the input and output of a recording encoder to enable an error correction code and a recording circuit to be used in common for digital tape recorders which have different numbers of tracks, e.g., n tracks and 2n tracks. When an error correction code is recorded in such a manner that one word in the digital data signal is divided into a plurality of symbols which are formed into an error correction code, a plurality of symbols of the same word are recorded at a position at which error correlation is strong, making effective use of the error correction capacity of the error correction code.”

U.S. Pat. No. 4,032,886 discloses a “concatenation technique for burst-error correction and synchronization” that uses a “system for processing a digital information bit stream and generating a data bit stream. The processing includes convolutional burst error correction encoding which is capable of correcting burst errors of length 2B, where B is any positive integer. Inherent in such systems are the requirements of 2B and 5B zero level bits at the beginning, and end, respectively, of the data bit stream. The processing further includes encoding n sync bits at the beginning of the data bit stream.”

It appears that none of the above-cited patent references addresses the use of a sampling method that mixes a symbol with symbols that are at a fixed time separation to provide for improved error correction method. Accordingly, it is an objective of the present invention to provide for an improved error correction method for use with bursty (noisy) communication channels such as satellite communication links and scratched compact disks, and the like.

### SUMMARY OF THE INVENTION

To meet the above and other objectives, the present invention comprises a sampling method that provides for robust error correction over bursty (noisy) communication channels. Typical bursty communication channels include satellite communication links and scratched compact disks, and the like.

The present sampling method mixes a symbol with symbols that are at a fixed time separation, compared to the conventional interleaving approach which mixes a given symbol with symbols that are in other fixed positions in the data stream regardless of data rate. In contrast to the conventional bit level or byte level interleaving approach, the span of error correction used in present sampling method has no limit. The present sampling method allows overlapping error correction.

In implementing the present sampling method, an incoming data stream is divided into symbols (bits, bytes, or words, for example). The data stream is then sampled in threads, with samples taken at fixed time intervals. By way of example, if the bursts are typically no longer than 70 microseconds long, every 100 microseconds, for example, is sampled. With cyclic redundancy check (CRC) correction, a correction word is inserted into the data stream.

In a second embodiment of the present method, the same symbol is included in more that one of the threads. If the threads only partially overlap, a noise burst that overwhelms one of the threads may be within the limits of another thread. Those symbols that overlap may be determined, allowing the remainder of the non-overlapped threads to be determined.

In the threaded sampling approach of the present invention, several independent threads are established (at least independent insofar as error correction is concerned). In the present invention, n registers are used. Each data symbol is copied onto a register (in this example, it is copied onto one register to make it substantially the same as the block interleaving example, but it may be onto two or more registers), and is then put onto an output buffer in an appropriate position.

The symbols get placed onto the output buffer and positions between them are filled with error correcting symbols calculated after a register gets filled. The transmission stream is drawn from this buffer. On the receiving side, the arriving symbols (both data and error correction symbols) get placed on their appropriate registers. The error detection and correction computations are performed and the corrected data symbols are placed on an output buffer in their correct positions. The output stream is drawn from this buffer.

The threaded sampling approach of the present invention is very flexible. For instance, one thread is put onto more than one register. Even though the data symbols only go on the transmission stream once, two sets of error symbols are generated. These may be set up to be overlapping so that one may achieve robustness not achievable by just doubling of the number of error symbols.

In the conventional block interleaving approach, the error symbols are grouped together at the end of a block of data. If too many errors occur in the error correction block, even though no data symbols were affected, the whole set, data symbols and error correction symbols, would be declared in error.

With the use of overlapping registers in accordance with the present invention, this does not happen, since only one register's error correcting symbols are affected. The unaffected error symbols can be used to generate the data bits. Alternatively, the two registers may be used to take every other symbol of a thread (in an overlapping fashion), thus spreading that thread out over twice the time extent, and reducing the impact of a given burst.

Whichever approach is selected, the other threads are not affected. The approach for the most significant bits (or symbols) can be different than that for the less significant bits (or symbols). Furthermore, as long as both transmit and receive sides have the range of capabilities, the choice of approaches can be communicated in a header portion, which sets up the mechanism.

### BRIEF DESCRIPTION OF THE DRAWINGS

The various features and advantages of the present invention may be more readily understood with reference to the following detailed description taken in conjunction with the accompanying drawing figures wherein like reference numerals designate like structural and in which:

FIGS. 1-3 illustrate a conventional block interleaving approach to error correction;

FIG. 4 illustrates a threaded sampling approach to error correction implemented in accordance with the principles of the present invention for use with bursty communication channels;

FIG. 4a illustrates a threaded sampling error correction device in accordance with the principles of the present invention;

FIG. 5 is a flow diagram illustrating a first embodiment of an error correction method for use with bursty communication channels in accordance with the principles of the present invention; and

FIG. 6 is a flow diagram illustrating a second embodiment of the error correction method.

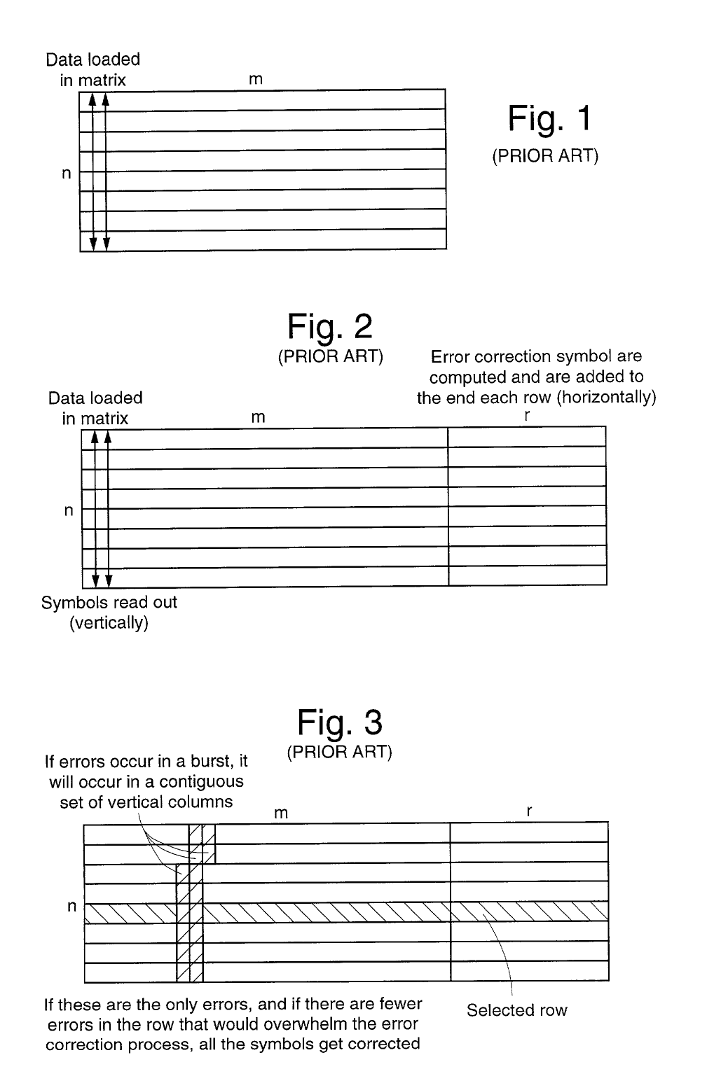

### DETAILED DESCRIPTION

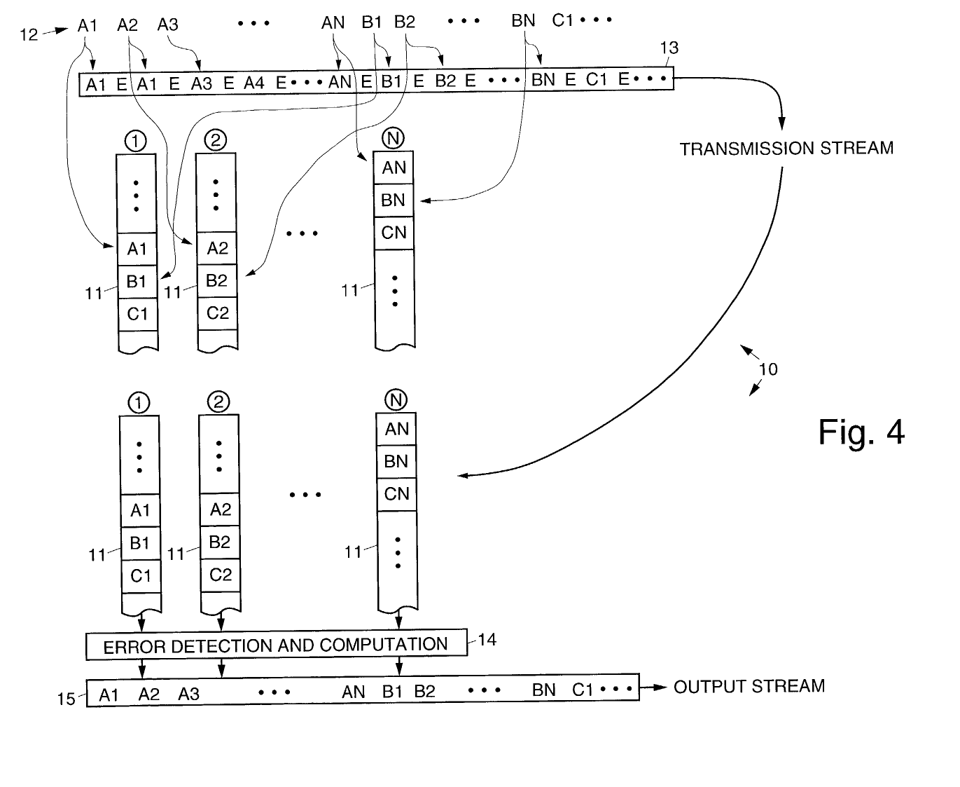

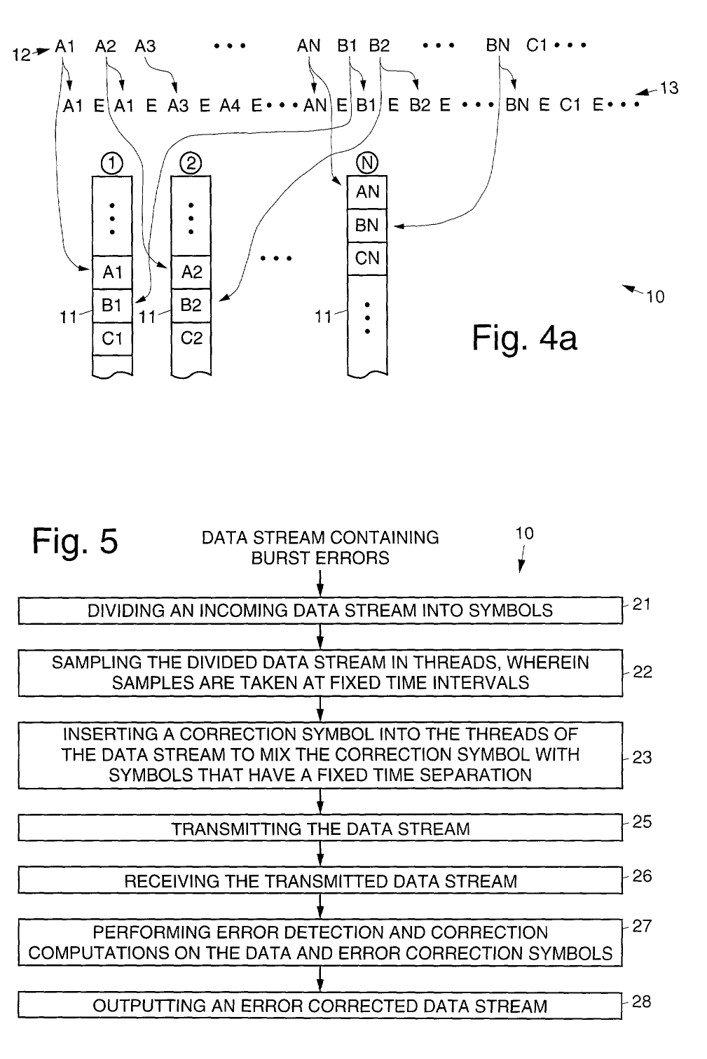

Referring now to FIG. 4, it illustrates a threaded sampling approach to error correction implemented in accordance with the principles of the present invention for use with bursty (noisy) communication channels. In the threaded sampling approach of the present invention, several independent threads are established, and which are independent insofar as error correction is concerned. To better understand the present invention, a threaded sampling example will be discussed below which has the same error correcting capability as the conventional block interleaving approach discussed previously.

With reference to FIG. 4, instead of an n-rowed matrix used in prior art approaches, n registers 11 are used. Each data symbol 12 that is to be transmitted is copied onto a register 11 (in this example, it is copied onto one register 11 to make it substantially the same as the block interleaving example, but it may be onto two or more registers 11). Each data symbol 12 is put onto a transmit output buffer 13 in an appropriate position. The symbols get placed onto the transmit output buffer 13 and positions between them are filled with error correcting symbols (E) calculated after a register 11 gets filled. The symbol transmission stream is drawn from the transmit output buffer 13 and transmitted.

On the receiving side of the communication channel, the arriving or received symbols, including both data and error correction symbols, get placed on their appropriate registers 11. Error detection and correction computations are performed 14 and the corrected data symbols are placed on a receive output buffer 15 in their correct positions. The output stream is drawn from the receive output buffer 15.

The threaded sampling approach of the present invention is flexible. For instance, one thread is put onto more than one register. Even though the data symbols only go on the transmission stream once, two sets of error symbols are generated. These may be set up to be overlapping so that one may achieve robustness not achievable by merely doubling of the number of error symbols.

In the conventional block interleaving approach, the error symbols are bunched (or grouped) together at the end of a block (set) of data. Burst errors have the same impact on the error correction symbols, insofar as error recovery, as errors that impact the data. In fact, if more than the correctable number of errors all occurred in the error correction block, even though no data symbols were affected, the whole set of data symbols and error correction symbols would be declared in error.

With the use of overlapping registers in accordance with the present invention, this does not happen, since only one register's error correcting symbols are affected. The unaffected error symbols can be used to generate the data bits.

Alternatively, the two registers may be used to take every other symbol of a thread (in an overlapping fashion), thus spreading that thread out over twice the time extent, and reducing the impact of a given burst.

Whichever approach is selected, the other threads are not affected. The approach for the most significant bits (or symbols) can be different than that for the less significant bits (or symbols). Further, as long as both transmit and receive sides have the range of capabilities, the choice of approaches can be communicated in a header portion, which sets up the mechanism.

FIG. 4a illustrates details of an exemplary threaded sampling error correction device 10 in accordance with the principles of the present invention. FIG. 4a shows the transmission side of the threaded sampling device 10. The threaded sampling device 10 takes a data stream 12 (D₆, D₇, D₈, . . . ), shown coming in on the left, and builds a transmission stream 19 (E₂, D₂, E₁, D₁, . . . ) shown on the right, that has additional symbols that are used on the receive side to detect and correct errors that occur during transmission. In particular, the threaded sampling device 10 provides protection against burst errors, but by a very different mechanism compared to conventional interleaver-based devices. The threaded sampling device 10 is designed and operates as follows.

(1) Incoming data is received in a data register 11. FIG. 4a shows the symbol D₆ in the data register 11. The residency time of the symbol in the register 11 may be set so that it corresponds to the data rate of the incoming data stream. While the symbol is in the data register 11, it may be copied, as explained in (3) below.

(2) From the data register 11, the symbol is moved to a queue 14 (stack 14), which is typically a FIFO queue 14. Conceivably, this symbol may be immediately placed on the output transmission stream 19, in contrast to other devices, which need to process a frame's worth of data to produce the error correction symbols and then place the frame's symbols on the transmission stream using interleaving. Although there is typically some buffering (not shown), the latency induced by the threaded sampling error correction device 10 is less than the conventional error correction devices.

(3) The data item selector, copier, mover 15 is a portion of the device 10 that carries out instructions as to which data items are to be copied, how many times, and to which stacks 14 the copies are moved. In this example, two copies of D₆ have been made, one pushed onto stack 2, and the other pushed onto stack n. The data item selector, copier, mover 15 is a programmable device and is not limited to a single mode such as error correction for a particular subsequence of the bits (see U.S. Pat. No. 4,700,363) or error correction for all bits (see U.S. Pat. Nos. 5,325,371, 5,392,299, or 5,491,701). Further, some data bits may be more protected than other data wherein they are involved in several different, overlapping error correction threads. These data bits do not have to be equally spaced in the data stream. For instance, they may be in particular positions of the address portion of IP headers. IP packets are of different lengths, although the header construction is standard, the bits can be algorithmically ascertained, but are not equidistant.

(4) The copies of the selected symbols are placed onto one or more of the stacks 14, as described in paragraph (3). Each of these stacks 14 represents a thread, since error correction symbols are calculated for the symbols on a given stack 14. At the receiving end, error correction is done on a stack by stack basis. Note that a given symbol (such as D₆ in the example depicted in FIG. 4a) may participate in more than one thread (that is, may be placed on more than one stack 14). If that is the case, it might not be able to be corrected from one thread, but may be from another. The corrected symbol may be fed back to the first thread's error correction computation 16 and, since the symbol is known, other symbol's of the first thread may now be corrected.

(5) When a given stack 14 has reached it's threshold (which may be different from stack to stack), the contents of the stack 14 are moved over to registers in an error correction computation unit 16 that calculates the error correction symbols for that stack 14. The error correction symbols are placed into an ECC queue 18. The error correction symbols may be grouped into a block appended to the end of the ECC queue 18 or they may be interspersed into the ECC queue 18, and subsequent ECC symbols may be interspersed with them. Note that different stacks 14 may be processed using different error correction algorithms such as Reed-Solomon of some mode or a Cyclic Redundancy Check, for example.

(6) The error correction symbols generated in (5) are placed onto the ECC queue 18. They may either be contiguous (in contrast to interleaved devices, such as is disclosed in U.S. Pat. Nos. 5,392,299 or 5,051,998) or they may be interspersed on the queue 18. In the latter case, the error correction device 10 may be implemented as a shift register and the symbols placed at their appropriate places.

(7) Symbols from both the data queue 17 and the ECC queue 18 are place onto the transmission stream 19. The symbols from each may be interspersed or they may be contiguous. However, within each type, they are consecutive.

The important difference between the present error correction device 10 and other devices is that it achieves its resistance to burst noise by computing the error symbol threads of data symbols which are drawn from widely dispersed locations without having to interleave the data symbols. The modular architecture allows one implementation to handle a wide variety of situations by altering the software that controls the various modules.

The receive side reverses the above-described process except that the stacks 14 hold both data and error symbols. Further, in cases where it is determined that a symbol has been erased in one stack 14, if it can be corrected in another stack 14, that corrected symbol is transmitted to the stack 14 where it is held as erased. Inserting the correct value for that symbol allows the error correction to now correct the remaining erased symbols.

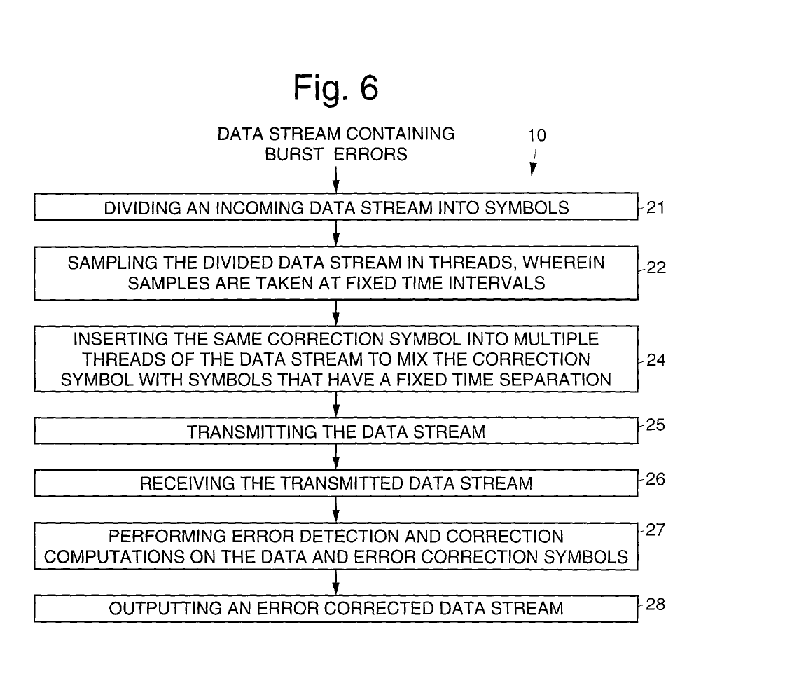

In view of the above, and for the purposes of completeness, FIGS. 5 and 6 illustrate two embodiments of methods in accordance with the present invention. FIG. 5 is a flow diagram illustrating a first embodiment of an error correction method 10 for use with a bursty communication channel in accordance with the principles of the present invention. The error correction method 10 comprises the following steps. An incoming data stream is divided 21 into symbols. The incoming data stream may comprise symbols in the form of bits, bytes, or words, for example. The divided data stream (bits, bytes, words) is then sampled 22 in threads, with samples taken at fixed time intervals. The fixed time intervals are slightly longer than the time interval of the bursts of data. For instance, if the bursts of data are typically no longer than 70 microseconds long, the data stream is sampled every 100 microseconds. The sampling method 10 thus mixes a correction symbol with symbols of the divided data stream that have a fixed time separation. When cyclic redundancy check (CRC) correction, for example, is implemented using the present method 10, a correction symbol (bit, byte, or word) is inserted 23 into the data (symbol) stream. The data stream is transmitted 25. The transmitted data stream is received 26. Error detection and correction computations are performed 27 on the data and error correction symbols. An error corrected data stream is output 28.

Referring to FIG. 6, it is a flow diagram illustrating a second embodiment of the error correction method 10. In the second embodiment of the error correction method 10, the incoming data stream is divided 21 into symbols. The divided data stream is then sampled 22 in threads, with samples taken at fixed time intervals. The same correction symbol is inserted 24 in more than one of the threads. The data stream is transmitted 25. The transmitted data stream is received 26. Error detection and correction computations are performed 27 on the data and error correction symbols. An error corrected data stream is output 28.

The threads are selected so that they partially overlap. By causing the threads to partially overlap in time, a noise burst on the channel that overwhelms one of the threads will be within the limits of another one of the threads. Those symbols that overlap may therefore be determined using the overlapping symbols of the threads that are not overwhelmed, thus allowing the remainder of the non-overlapped threads to be determined.

Thus, and in accordance with the present invention, instead of framing the symbols and computing the error symbols, the present method sends the symbols in their natural order, bins copies in M bits, computes the error symbols, and send the symbols out when the bin is full. The binning can be staggered so that the error correcting symbols are distributed throughout the transmitted stream. The power of the present invention comes from spreading large errors over several rows so that the error correcting symbols can correct the whole row (typically N error correcting symbols corrects N/2 errors).

Since each bin is independent of the rest, different amounts of error correction can be used for different bins. For instance, in Asynchronous Transfer Mode (ATM) cells, damage to the 5 bytes of the cell header block can be much more damaging than damage to the 48 bytes of data. There would be 58 bins where the ATM header block cells are captured twice. Thus, twice as many error correcting symbols get transmitted for them.

Thus, an improved error correction method for use with bursty communication channels has been disclosed. It is to be understood that the described embodiment is merely illustrative of some of the many specific embodiments which represent applications of the principles of the present invention. Clearly, numerous and other arrangements can be readily devised by those skilled in the art without departing from the scope of the invention.

What is claimed is:

1. An error correction method for use with a noisy communication channel, said method comprising the steps of:
dividing a data stream into symbols;
sampling the divided data stream in threads, wherein samples are taken at fixed 5 time intervals;
inserting a correction symbol into the data stream to mix the correction symbol with data symbols that have a fixed time separation;
transmitting the data stream;
receiving the transmitted data stream;
performing error detection and correction computations on the data and error correction symbols; and
outputting an error corrected data stream.

2. The method of claim 1 wherein the bursty communication channel comprises a satellite communication link.

3. The method of claim 1 wherein the bursty communication channel comprises a scratched compact disk.

4. The method of claim 1 wherein the incoming data stream comprises symbols in the form of bits.

5. The method of claim 1 wherein the incoming data stream comprises symbols in the form of bytes.

6. The method of claim 1 wherein the incoming data stream comprises symbols in the form of words.

7. The method of claim 1 wherein samples are taken at fixed time intervals that are longer than the time interval of the bursts of data.

8. The method of claim 1 wherein the step of performing error detection and correction comprises performing cyclic redundancy check error correction.

9. The method of claim 1 wherein the step of inserting a correction symbol into the data stream comprises the step of inserting the same correction symbol is in more than one thread.

10. An error correction method for use with a noisy communication channel, said method comprising the steps of:
copying each data symbol that is to be transmitted onto a register;
placing each data symbol onto a transmit output buffer in a predetermined position, wherein positions between each data symbol are filled with error correcting symbols calculated after a register gets filled;
transmitting a symbol transmission stream from the transmit output buffer;
receiving the transmitted transmission stream;
placing data and error correction symbols from the symbol transmission stream on predetermined registers;
performing error detection and correction computations on the data and error correction symbols;
placing the corrected data symbols on a receive output buffer in their correct positions; and
outputting an error corrected data stream from the receive output buffer.

11. The method of claim 10 wherein the bursty communication channel comprises a satellite communication link.

12. The method of claim 10 wherein the bursty communication channel comprises a scratched compact disk.

13. The method of claim 10 wherein the incoming data stream comprises symbols in the form of bits.

14. The method of claim 10 wherein the incoming data stream comprises symbols in the form of bytes.

15. The method of claim 10 wherein the incoming data stream comprises symbols in the form of words.

16. The method of claim 10 wherein samples are taken at fixed time intervals that are longer than the time interval of the bursts of data.

17. The method of claim 10 wherein the step of performing error detection and correction comprises performing cyclic redundancy check error correction.

18. The method of claim 10 wherein the step of inserting a correction symbol into the data stream comprises the step of inserting the same correction symbol is in more than one thread.
